(19) United States
(12) Patent Application Publication
(10) Pub. No.: US 2006/0001145 A1
(43) Pub. Date: Jan. 5, 2006

(54) Wafer level mounting frame with passive components integration for ball grid array packaging

(75) Inventors: Chi-Shen Ho, Fremont, CA (US); Chang-Ming Lin, San Jose, CA (US)

Correspondence Address: TUNG & ASSOCIATES;Suite 120, 838 W. Long Lake Road, Bloomfield Hills, MI, 48302, US

(73) Assignee: Aptos Corporation

(21) Appl. No.: 10/884,715

(22) Filed: Jul. 3, 2004

(51) Int. Cl. H01L 23/552

(52) U.S. Cl. 257/690

(57) ABSTRACT

A mounting frame substrate having a cavity formed therein and a semiconductor chip in the cavity of the substrate. The semiconductor chip includes bond pads along the periphery thereof and forming a redistribution trace connected to a bond pad of the chip.

### FIELD OF THE INVENTION

This invention related to semiconductor products and processes, and more particularly to semiconductor packaging and methods of making the same.

### BACKGROUND OF THE INVENTION

Presently, even the cheapest plastic ball grid arrays (BGAs) are generally slightly more expensive than their QFP counterparts, especially for I/O numbers below 250 or thereabout. This cost increase at the package level may turn into an overall cost decrease at board level owing to the potential higher assembly yields. However, BGA packages involving carrier substrates with more than two layers are not likely to compete with the cost of QFP at lower pin counts. The reason for the higher cost of the PBGAs is primarily in the material cost of the high-temperature BT epoxy substrate and the costs of the fine line circuitry technology required.

This invention provides alternatives to the prior art.

### SUMMARY OF THE INVENTION

One embodiment of the invention includes a method of providing a substrate having a cavity formed therein and placing a semiconductor chip in the cavity of the substrate. The semiconductor chip includes bond pads along the periphery thereof and a redistribution trace is connected to a bond pad of the chip.

A microelectronic assembly comprising a substrate having a cavity formed therein, and a semiconductor chip in the cavity and attached to the substrate, the semiconductor chip comprising bond pads along the periphery thereof and a redistribution trace connected to a bond pad of the chip, and wherein an upper surface of the substrate and an upper surface of the chip are substantially in the same plane.

These and other embodiment will be apparent from the following brief description of the drawings, detailed description of exemplary embodiments and appended claims and drawings.

### BRIEF DESCRIPTION OF THE DRAWINGS

FIG. 1A illustrates one embodiment of the invention including a method of providing a substrate with a photoresist layer or other mask material selectively patterned on the substrate wherein the photoresist includes at least one opening therethrough.

FIG. 1B illustrates one embodiment of the invention including a method of etching a cavity in the substrate and removing the photoresist layer.

FIG. 1C illustrates one embodiment of the invention including a method of placing a semiconductor die (chip) in the cavity and attaching the die to the substrate.

FIG. 1D illustrates one embodiment of the invention including a method of forming a first dielectric layer over the substrate and the die.

FIG. 1E illustrates one embodiment of the invention including a method of forming a first set of a plurality of vias in the first dielectric and wherein the vias extend down to the die.

FIG. 1F illustrates one embodiment of the invention including a method of patterning a first set of electrically conductive traces over the first dielectric layer and down into of the vias of the first dielectric layer extending to the die.

FIG. 1G illustrates one embodiment of the invention including a method of forming a second dielectric layer over the first electrically conductive traces.

FIG. 1H illustrates one embodiment of the invention including a method of forming a second set of vias in the second dielectric layer.

FIG. 1I illustrates one embodiment of the invention including a method of forming a second set of electrically conductive traces over the second dielectric layer and down into at least one of the vias of the second set to contract the first electrically conductive trace.

FIG. 1J illustrates one embodiment of the invention including a method of forming a third dielectric layer over the second set of electrically conductive traces.

FIG. 1K illustrates one embodiment of the invention including a method of forming a third set of vias in the third dielectric layer.

FIG. 1L illustrates one embodiment of the invention including a method of dicing the substrate.

FIG. 1M illustrates one embodiment of the invention including a method of attaching a flexible printed circuit by an electrically conductive bump extending through one of the vias of the third set and down to one of the second electrically conductive traces.

FIG. 2 illustrates a microelectronic device having a wafer level mounting frame according to one embodiment of the invention.

FIG. 3 illustrates a partial view, with portions broken away, of a semiconductor chip with bond pads useful in the present invention.

FIG. 4 illustrates a partial view, with portions broken away, of a redistribution trace with landing pads useful in the present invention.

### DETAILED DESCRIPTION OF EXEMPLARY EMBODIMENTS

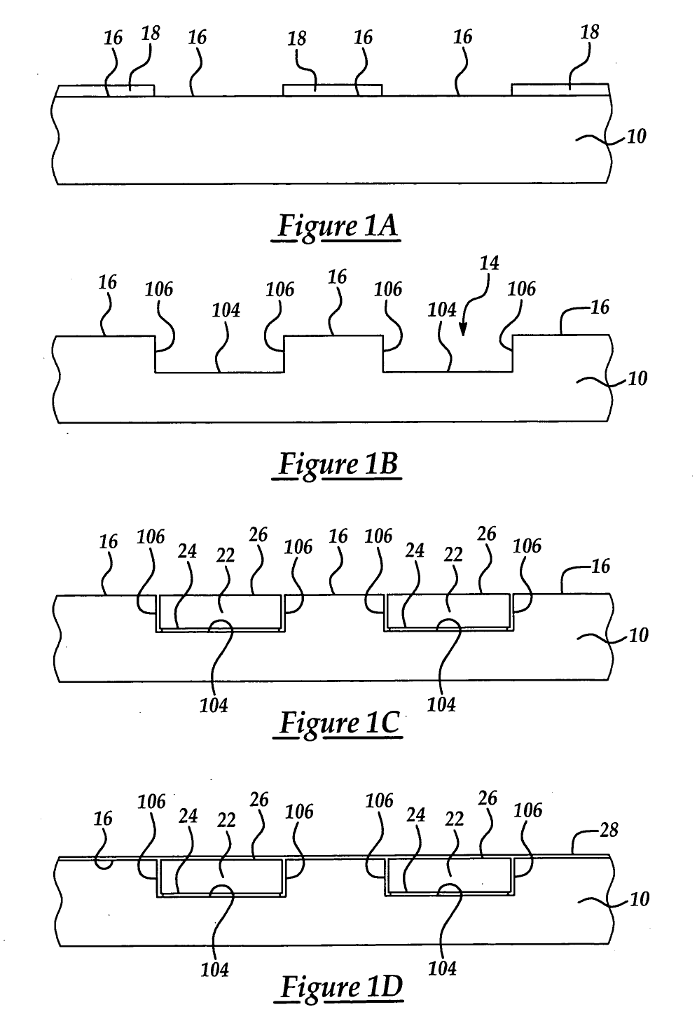

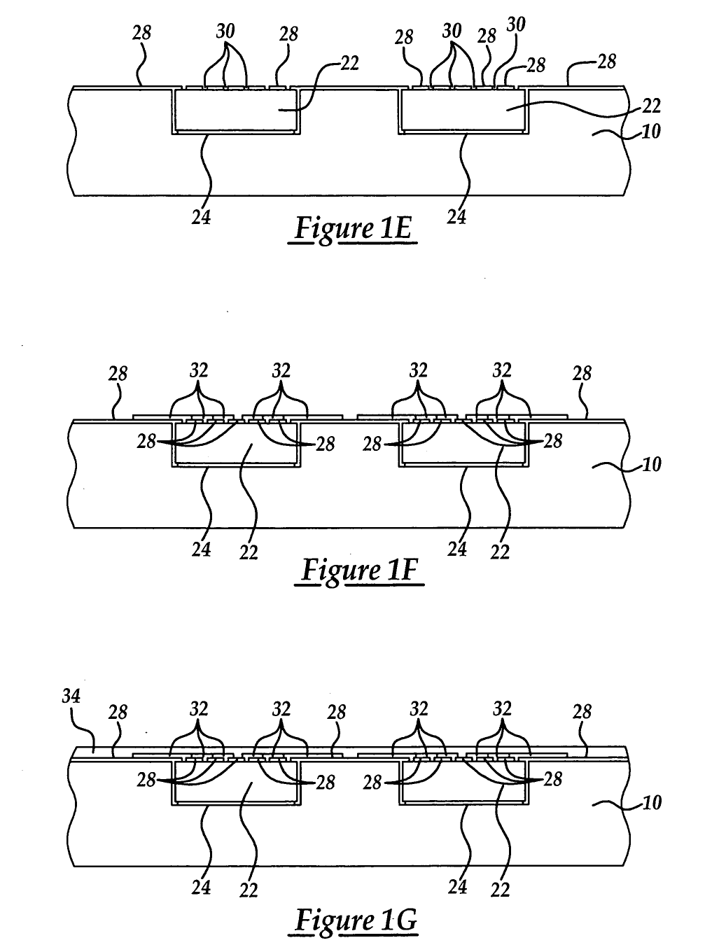

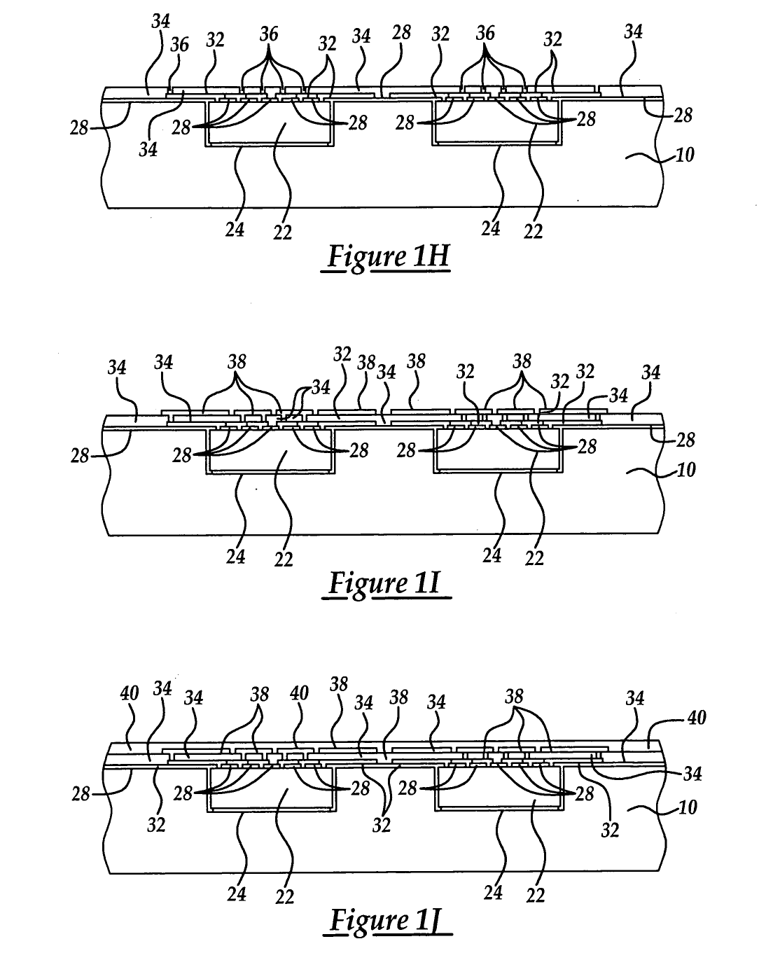

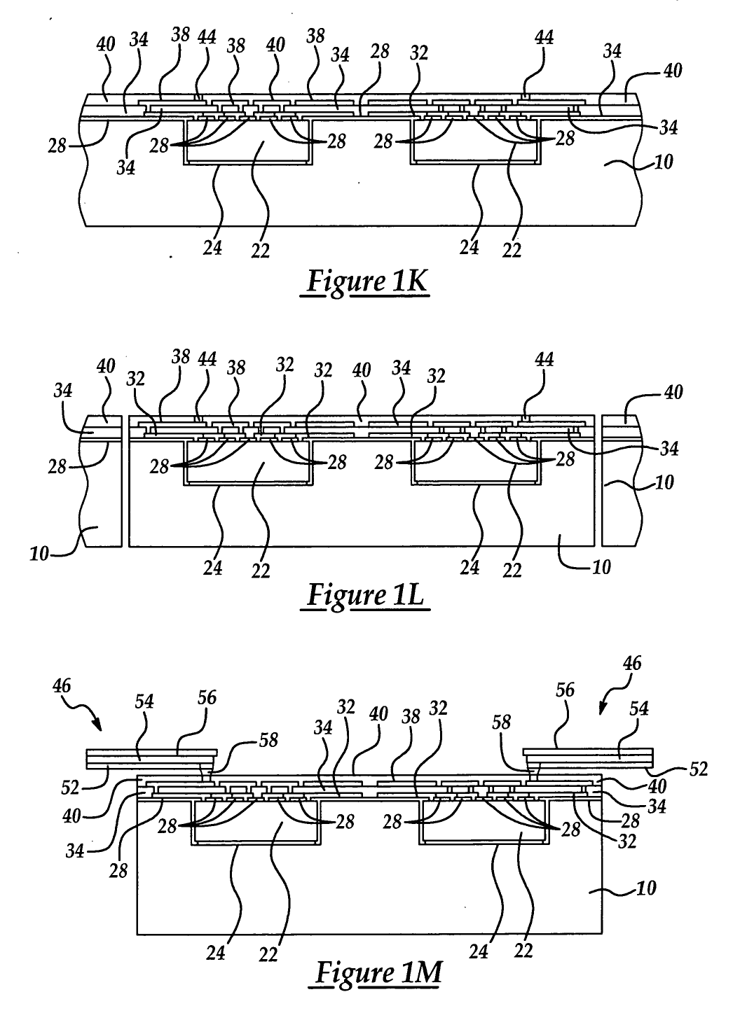

One embodiment of the invention includes a method of providing a wafer level mounting frame such as a substrate 10 having at least one cavity 14 formed in the upper surface 16 thereof, as shown in FIG. 1B. The substrate 10 may be made from any material known to those skilled in the art for making microelectronic substrates including, but not limited to, a silicon wafer, solids polymers, plastics, ceramics, fiberglass materials. The cavity 14 may be made by any method known to those skilled in the art such as milling, wet or dry etching, laser removal, molding, stamping, or selective growth of a layer to define a cavity in a non-grown area. In one embodiment of the invention, the cavity 14 is formed by selectively patterning a photoresist layer over the substrate 10 and wherein the photoresist layer 18 has an opening formed therein exposing an upper surface 16 of the substrate 10. The cavity is defined by a bottom cavity surface 104 of the substrate and by substantially vertical sidewalls 106 or inclined sidewalls 54, 74 extending upward from the bottom cavity surface 104. As shown in FIG. 1C, a semiconductor chip or die 22 is placed in the cavity 14 and attached to the substrate 10 by, for example, an adhesive layer 24 (i.e., an epoxy resin). The chip 22 may be spaced a distance from sidewalls 106. It may be desirable to make sure that the upper surface 26 of the die 22 is flush with the upper surface 16 of the substrate 10. In one embodiment of the invention, the cavity 14 is formed to a depth of 120 μm and a chip 100 μm is placed on a 20 μm thick adhesive layer in the bottom of the cavity 14.

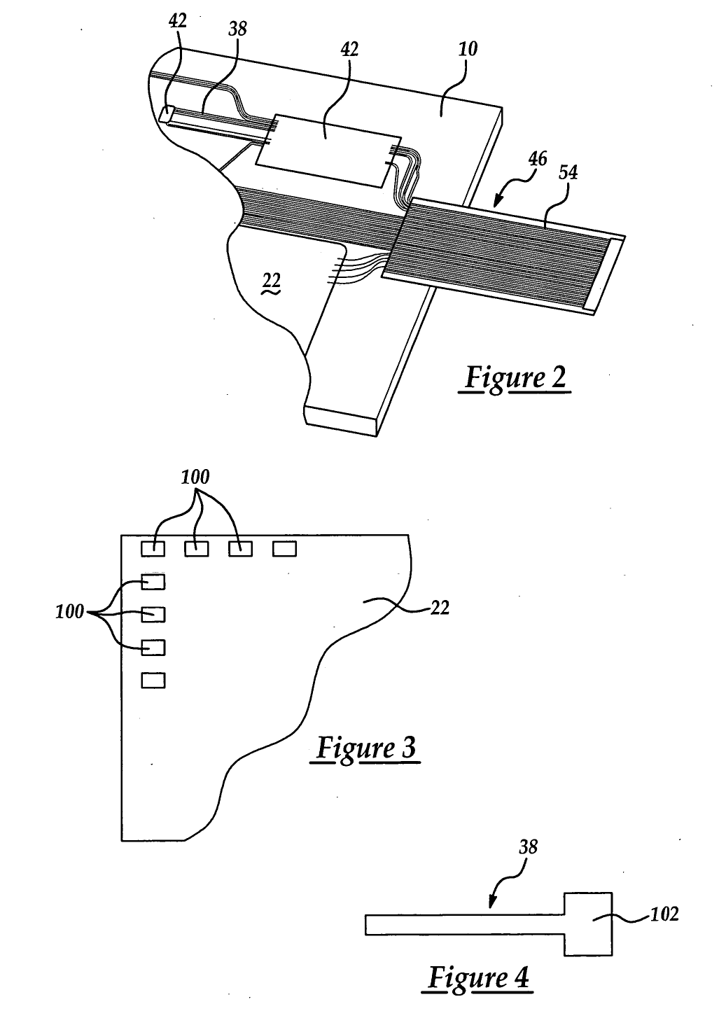

As shown in FIG. 1D, a first dielectric layer 28 may be formed over the substrate 10 and the die 22. Suitable dielectric layers include, but are not limited to, BCB (bisbenzocyclobutene) or polyimide layers, for example 10 μm thick. As shown in FIG. 1E, a first set of vias 30 may be formed in the first dielectric layer 28, for example, by reactive ion etching using a patterned photoresist layer (not shown) that is applied, and then removed after the etching, in a manner known to those skilled in the art. The first set of vias 30 are each position to expose an individual bond pad (best seen in FIG. 3) on the substrate 10. As shown in FIG. 1F, a first set of redistribution traces, such as a first set of electrically conductive trace 32 may be formed over the first dielectric layer 28 and wherein each trace 32 individually extends into one of the first set of vias 30 and onto the one of the bond pads 100 of the substrate 10. Each of the traces 32 of the first set of redistribution trace extends horizontally from the bond pad that it s connected to. In one embodiment, at least some of the traces 32 of the first set of redistribution traces each extends horizontally from bond pad located near the periphery of the chip to a location more centrally positioned over the chip where there is more room to make electrical connect to a bond pad that is at the terminal end of the redistribution trace 32. The electrically conductive traces 32 may be formed by sputtering, physical vapor deposition or plating, using patterning that is either additive of subtractive. A suitable materials for the traces 32 includes, but is not limited to Cu/Ni.

Referring now to FIG. 1G, a second dielectric layer 34, such as a polyimide, may be formed over the first set of redistribution traces 32. A second set of vias 36, as shown in FIG. 1H, is formed in the second dielectric layer 34, for example, by reactive ion etching using a patterned photoresist layer (not shown) that is applied, and then removed after the etching, in a manner known to those skilled in the art. As shown in FIG. 11, a second set of electrically conductive traces 38 are formed over the second dielectric layer 34 and wherein at least one trace 38 individually extends into one of the vias of the second set of vias 36. The second set of traces 38 may be formed by sputtering, physical vapor deposition or plating, using patterning that is either additive of subtractive. A suitable material for the traces 38 includes, but is not limited to Cu/Ni. The second set of traces 38 may be connected to additional components 42 such as resistors, capacitors and inductors on the substrate 10, best seen in FIG. 2.

As shown in FIG. 1J, a third dielectric layer 40 is formed over the substrate 10 and the second set of traces 38. The third dielectric layer 40 may be formed, for example, by spinning on a polyimide layer to a thickness of about 10 μm. As shown in FIG. 1K, a third set of vias 44 are formed in the third dielectric layer 40 down to landing pads 102 (best seen in FIG. 4) on the second set of traces 38.

As shown in FIG. 1L, the substrate 10 may be diced (cut) using, for example, a saw or laser. As shown in FIG. 1M, a flexible printed circuit 46 may be attached to the substrate 10. The flexible printed circuit 46 may include a flexible bottom layer 52 such as a polyimide layer, a third set of electrically conductive traces 54 overlying the bottom layer 52, and a top layer 56 such as a polyimide layer 56 overlying the third set of traces 54. An electrical connection bump 58, such as a solder bump, may be connected to one of the traces 54 of the third set. The electrical connection bump 58 extends through one of the vias 44 of the third set to make electrical connection to the landing pad 102 (FIG. 4) of one of the traces 38 of the second set.

1-27. (canceled)

28. A microelectronics assembly comprising:
a substrate having a cavity formed therein and a semiconductor chip in the cavity and attached to the substrate, the semiconductor chip comprising bond pads along the periphery thereof and a redistribution trace connected to a bond pad of the chip, and wherein an upper surface of the substrate and an upper surface of the chip are substantially in the same plane.

29. A product comprising:
a substrate having at least one cavity formed therein;
a semiconductor chip being received in the cavity and attached to the substrate at least a bottom cavity surface of the substrate that defines the cavity, and wherein the chip comprises bond pads on at least one face and wherein the bond pads face upward and away from the bottom cavity surface;
a first dielectric layer over an upper surface of the substrate and the chip and having a first set of vias in the first dielectric layer, each via of the first set of vias extending to one of the bond pads on the chip;
a first set of redistribution traces over the first dielectric and wherein each trace of the first set of redistribution traces extends into one of the vias of the first set of vias to make electrical contact to one of the bond pads on the chip.

30. A method as set forth in claim 29 wherein the chip is positioned in the cavity so that the bond pads of the chip are at the same level or below the upper of the substrate.

31. A product as set forth in claim 29 wherein the substrate comprises silicon wafer.

32. A product as set forth in claim 29 wherein the substrate comprises at least one of a polymer, a plastic, a ceramic, and a fiberglass material.

33. A product as set forth in claim 29 further comprising a second dielectric layer over the substrate and the first set of redistribution traces and a second set of vias in the second dielectric, wherein each one of the vias of the second set extends down to a portion of one of the redistribution traces of the first set of redistribution traces;
a second set of electrically conductive traces over the second dielectric layer and wherein one of the second set of electrically conductive trace extends down into one of the vias of the second set connecting to one of the traces of the first set of redistribution traces.

34. A product as set forth in claim 33 further comprising a third dielectric layer overlying the second dielectric layer and the second set of electrically conductive traces and a third set of vias in the third dielectric, wherein each one of the vias of the third set extends down to a portion of one of the electrically conductive traces of the second set of electrically conductive traces.

35. A product as set forth in claim 35 further comprising a flexible printed circuit attached to the second set of electrically conductive traces.

36. A method as set forth in claim 13 wherein each one of the traces of the second set of electrically conductive traces comprises a landing pad.

37. A product as set forth in claim 34 further comprising a flexible printed circuit attached to the second set of electrically conductive traces, and wherein the flexible printed circuit comprises a third set of electrically conductive traces and each one of the traces of the third set having an electrically conductive connection bump connect thereto and the bump extending into one of the vias of the third set connecting to a landing pad of one of the traces of the second set of electrically conductive traces.

38. A product as set forth in claim 37 wherein the flexible printed circuit comprises a first polyimide layer, a plurality of electrically conductive traces overlying the first polyimide layer and a second polyimide layer over layer the plurality of electrically conductive trace overlying the first polyimide layer.

39. A product comprising:
a substrate having at least one cavity formed therein;
a semiconductor chip in the cavity and the chip attached to the substrate at least at a bottom cavity surface of the substrate that defines the cavity, and wherein the chip comprises bond pads on at least one face and wherein the chip is placed in the cavity with the bond pads face upward and away from the bottom cavity surface;
a first dielectric layer over an upper surface of the substrate and the chip and a first set of vias in the first dielectric layer, each via of the first set of vias extending to one of the bond pads on the chip;
a first set of redistribution layers over the first dielectric and wherein each trace of the first set of redistribution traces extends into one of the vias of the first set of vias and making electrical contact to one of the bond pads on the chip;
a flexible printed circuit electrically connected to the redistribution traces.

40. A method as set forth in claim 39 wherein the flexible printed circuit comprises a third set of electrically conductive traces and wherein the each one of the traces of the first set of redistribution traces is individually electrically connected to one of the traces of a second set of electrically conductive traces, and each one of the traces of the second set of electrically conductive traces is individually electrically connected to one of the traces of the flexible printed circuit.
